(19) United States
(12) Patent Application Publication
(10) Pub. No.: US 2003/0123680 A1
(43) Pub. Date: Jul. 3, 2003

(54) Volume control system and method of volume control for portable computer

(75) Inventors: Dong-ho Lee, Suwon City (KR); Young-Hwan Park, Suwon city (KR)

Correspondence Address: STAAS & HALSEY LLP, 700 11TH STREET, NW, SUITE 500, WASHINGTON, DC, 20001, US

(73) Assignee: Samsung Electronics Co., Ltd., Suwon-city (KR)

(21) Appl. No.: 10/329,446

(22) Filed: Dec. 27, 2002

(30) Foreign Application Priority Data
Jan. 3, 2002 (KR) 2002-221

(51) Int. Cl. G06F 17/00; H03G 3/00

(52) U.S. Cl. 381/104; 381/107; 700/94

(57) ABSTRACT

A system for adjusting a sound signal output to a speaker of a portable computer based on an amount of background noise external to the personal computer. A noise sensor senses the external noise and a micro controller calculates an average of the external noise for a predetermined period of time and adjusts a volume level controller based on a predetermined volume set up table which lists volume levels corresponding to levels of the external noise. Alternatively, the micro controller calculates an average noise level for a current predetermined period of time and adjusts the volume level controller based on comparing the current calculated average noise with a calculated average noise for a previous predetermined period of time. If the external noise increases, the output sound signal is increased and if the external noise decreases, the output sound signal is decreased.

### CROSS REFERENCE TO RELATED APPLICATIONS

This application claims the benefit of Korean Application No. 2002-221 filed Jan. 3, 2002, in the Korean Patent Office, the disclosure of which is incorporated herein by reference.

### BACKGROUND OF THE INVENTION

1. Field of the Invention

The present invention relates to a sound volume control system and a method of controlling sound volume for a portable computer, and more particularly, to a sound volume control system and a method of controlling sound volume for a portable computer wherein a volume auto-control function enables a user to hear a sound of the portable computer properly without interruption from noise external to the computer.

2. Description of the Related Art

A computer system may be operated as a reproducing device which reproduces a multimedia presentation including a sound, graphics, a motion picture, etc., as an Internet phone using the Internet, as an audio device using a CD-ROM (compact disk read only memory) drive, etc. Accordingly, the computer system is generally equipped with a speaker for reproducing the sound, and a microphone for making a telephone call using the Internet, participating in a voice chat, etc.

However, while a sound is reproduced in constant volume controlled by a user, if external noise (background noise) is increased, a user relatively feels that the controlled volume is low, whereas if the external noise is decreased, a user relatively feels that the controlled volume is high. Particularly, in a case of a portable computer, because the portable computer is frequently used outside an enclosed space or during a user's travels in which the external noise is frequently changed, a user must control the volume of the sound manually according to a change of the external noise.

To avoid this inconvenience, there has been proposed a method entitled “automatic speaker volume control method (Japanese Patent First Publication 1998-75496)”, in which the volume of the sound is automatically controlled according to a change of the external noise.

However, to perform a conventional volume auto-control function, a predetermined process is needed for calculating volume level to be outputted according to a change of the external noise. Further, a separate A/D converter is needed for processing the analog external noise into a digital value for the calculation. Consequently, to perform the conventional volume auto-control function, additional circuit elements such as the A/D converter, a calculation part, etc., are needed.

### SUMMARY OF THE INVENTION

Accordingly, the present invention has been made keeping in mind the above-described shortcomings and user's need, and an object of the present invention is to provide a volume control system and a method of volume control for a portable computer, in which a number of circuit elements for a volume auto-control function is decreased.

Additional objects and advantages of the invention will be set forth in part in the description which follows, and, in part, will be obvious from the description, or may be learned by practice of the invention.

The above and other objects of the present invention are accomplished by a provision of a volume control system for a portable computer having a speaker, a volume controller which controls volume according to a volume control signal; an audio circuit part which adjusts a volume of sound in response to the volume control signal and outputs a sound signal having the adjusted volume to the speaker, the volume control system further comprising: a user selection part which selects a volume auto-control function; a noise sensor which senses a noise from outside the computer; a volume set up table in which volume levels corresponding to noise levels graded by the loudness of the external noise are listed; and a micro controller which determines a noise level based on a loudness of the noise sensed by the noise sensor, reads a volume level corresponding to the determined noise level from the volume set up table, and controls the volume controller to adjust the volume of the sound based on the read volume level where the volume auto-control function is selected through the user selection part.

The noise sensor may comprise a microphone. The micro controller includes an A/D converter pin which inputs an analog noise signal corresponding to the external noise to the micro controller for conversion into a digital signal by the micro controller.

According to another aspect of the present invention, the above and other objects of the invention are also achieved by the provision of a method of sound volume control for a portable computer, the method comprising storing a volume set up table in which volume levels corresponding to noise levels graded by loudness of an external noise are previously listed; sensing the external noise; determining the noise level of the sensed noise; and adjusting the volume of the sound according to the determined noise level based on the volume set up table.

### BRIEF DESCRIPTION OF THE DRAWINGS

The present invention will be better understood and its various objects and advantages will be more fully appreciated from the following description taken in conjunction with the accompanying drawings, in which:

FIG. 1 is a perspective view of a portable computer;

FIG. 2 is a block diagram illustrating a volume control system of the portable computer according to the present invention;

FIG. 3 is a flow chart illustrating an embodiment of a volume control method according to the present invention; and

FIG. 4 is a flow chart illustrating another embodiment of the volume control method according to the present invention.

### DESCRIPTION OF THE PREFERRED EMBODIMENTS

Reference will now be made in detail to the present embodiments of the present invention, examples of which are illustrated in the accompanying drawings, wherein like reference numerals refer to like elements throughout.

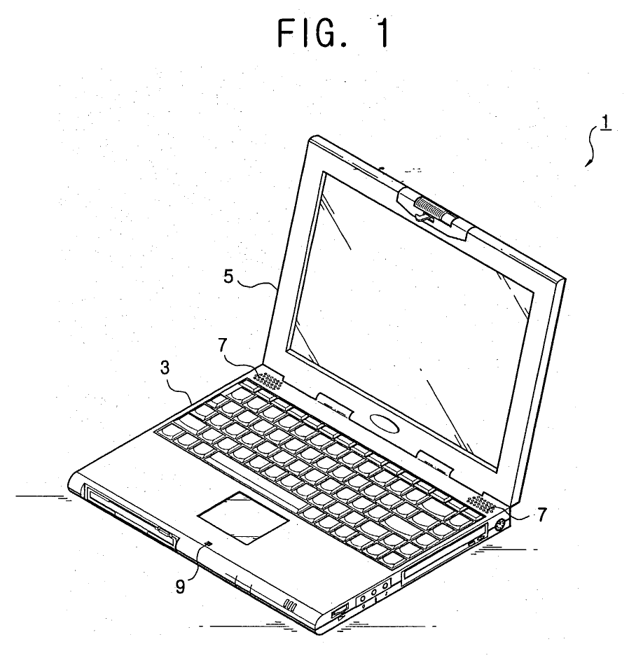

As shown in FIG. 1, a portable computer 1 comprises a main body 3 equipped with a plurality of hardware modules, and a display panel 5 displaying a video signal received from the main body 3. The main body 3 is provided with a speaker 7 and a microphone 9.

The speaker 7 is employed as an output unit producing a warning sound, effective sound, etc., or reproducing audio data. When a user plays audio files or an audio CD through the main body 3, the speaker 7 produces a sound from the audio files or the CD.

The microphone 9 is employed as an input unit which receives sound from outside the computer 1 and converts the outside sound into an electric analog signal. The microphone 9 receives not only a user's voice but also other external noises around the portable computer 1.

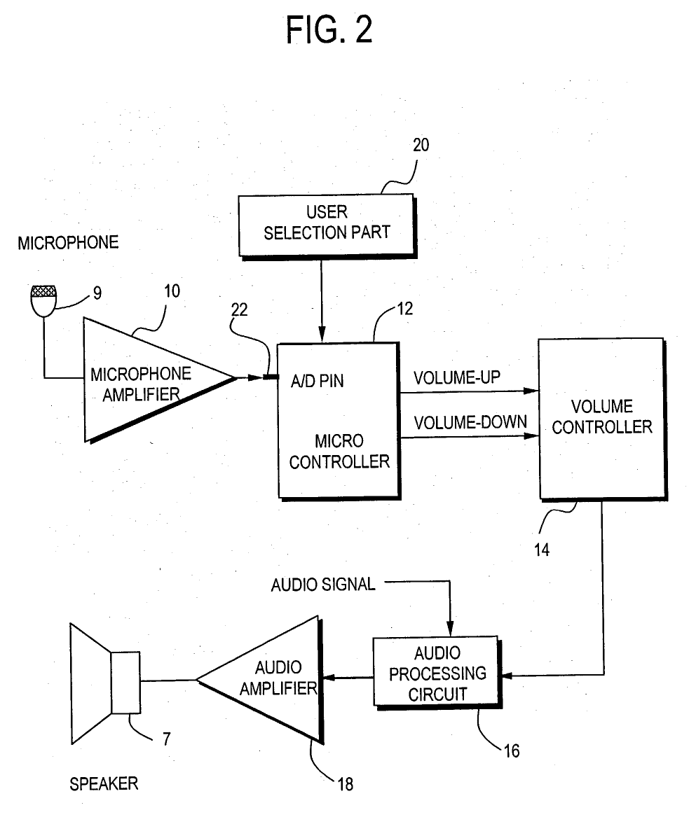

As shown in FIG. 2, a volume control system according to the present invention comprises a user selection part 20 for selecting a volume auto-control function, an audio processing circuit 16 which processes an audio signal, an audio amplifier 18 which amplifies the audio signal output from the audio processing circuit 16, a speaker 7 which outputs a sound corresponding to the amplified audio signal, a microphone 9 which receives a sound including external or background noise from outside the computer and outputs an analog signal, a microphone amplifier 10 which amplifies the analog signal output from the microphone 9, a micro controller 12 which generates a volume control signal in response to the amplified analog signal received from the microphone amplifier 10, and a volume controller 14 which controls the audio processing circuit 16 in response to the volume control signal input to the volume controller from the micro controller 12, to adjust a volume of the sound.

The user selection part 20 enables a user to select the volume auto-control function or to set up an operating environment of the volume control system. A user selects the volume auto-control function or sets up the operating environment of the volume control system through an active window displayed on the display panel 5. Further, in order to select the volume auto-control function or to set up the operating environment of the volume control system, the main body 3 may be provided with a predetermined button, or a function key of a keyboard may be used.

The audio processing circuit 16 processes a sound signal with a CODEC (coder/decoder), a converter, etc., and regulates an amplification rate of the sound signal in response to the volume control signal input from the volume controller 14, thereby adjusting the volume of the sound.

The microphone 9 receives the noise from the outside and converts the external noise into an electric analog noise signal. The converted electric analog noise signal is amplified by the microphone amplifier 10, and transmitted to the micro controller 12.

The micro controller 12 comprises an A/D converter pin through which the amplified analog noise signal is converted into a digital signal.

Further, the micro controller 12 comprises a volume set up table in which volume levels corresponding to the noise levels graded by loudness of the external noise are listed. By way of example, the volume set up table is illustrated in Table 1.

TABLE 1

| Noise Level | Volume Level |
|---|---|
| 9 | Max(Maximum Volume) |
| 8 | Max-1 |
| 7 | Max-2 |
| 6 | Max-3 |
| 5 | Max-4 |
| 4 | Max-5 |
| 3 | Max-6 |
| 2 | Mid(Middle Volume) |
| 1 | Mid-1 |
| 0 | Mid-2 |

The volume set up table is stored in a memory (not shown) of the micro controller 12. However, instead of the volume set up table, a software program may control the micro controller 12 to be operated corresponding to the volume set up table.

Thus, when a user selects the volume auto-control function through the user selection part 20, the analog noise signal input through the microphone 9 is transmitted to the micro controller 12. The analog noise signal is converted into a digital signal by going through the A/D converter pin 22, and the digital signal is then sensed by the micro controller 12. The micro controller 12 determines the noise level of the noise transmitted from the microphone 9 on the basis of the volume set up table, and transmits a volume control signal to the volume controller 14 based on the volume level corresponding to the determined noise level. Therefore, the volume of the sound to be outputted through the speaker 7 is automatically controlled on the basis of the volume set up table in which the volume levels are listed according to the loudness of the noise.

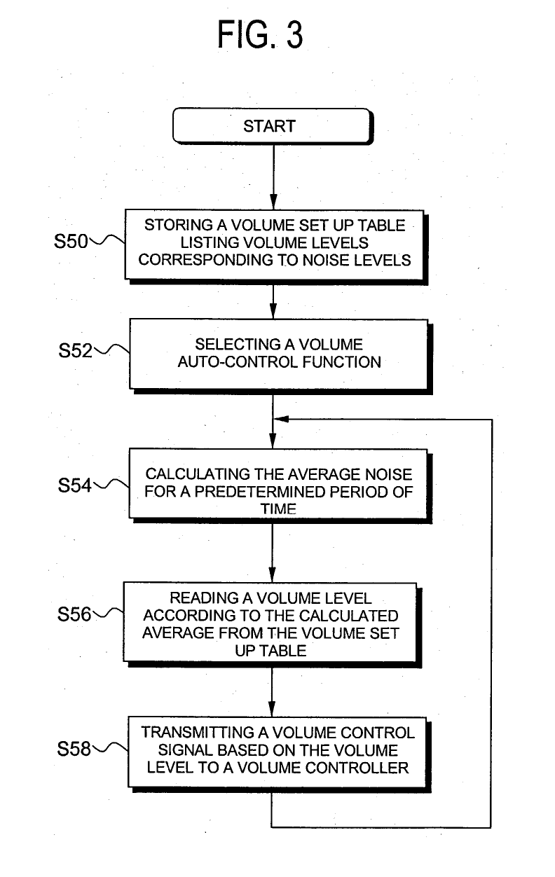

With the configuration of the volume control system shown in FIG. 2, a method of the volume control will be described referring to FIG. 3.

First, the volume set up table in which the volume levels corresponding to the predetermined noise levels graded by the loudness of the external noise are listed is stored in the memory of the micro controller 12 at operation S50.

Where the user selects the volume auto-control function through the user selection part 20 at operation S52, the micro controller 12 receives the external noise through the microphone 9, and calculates an average of the input external noise for a predetermined period of time at operation S54. The micro controller 12 determines the noise level on the basis of the calculated average of the external noise, and reads the volume level corresponding to the determined noise level from the volume set up table at operation S56. The micro controller 12 transmits the volume control signal based on the volume level from the volume set up table to the volume controller 14 at operation S58, so that the sound is output through the speaker 7 on the basis of the read volume level from the volume set up table.

Since the micro controller 12 calculates the average of the external noise inputted for the predetermined period of time and determines the noise level on the basis of the calculated average of the external noise, the volume level does not suddenly change even if the external noise suddenly changes.

Thus, the volume of the sound is automatically controlled according to a change of the external noise even if a user does not manually control the volume of the sound.

As described above, according to the present invention, an external noise is input to an A/D converter pin of a micro controller which transmits a volume control signal to a volume controller based on a value selected from a volume set up table in which predetermined volume levels corresponding to noise levels are listed, wherein the set up table is stored in the memory of the micro controller.

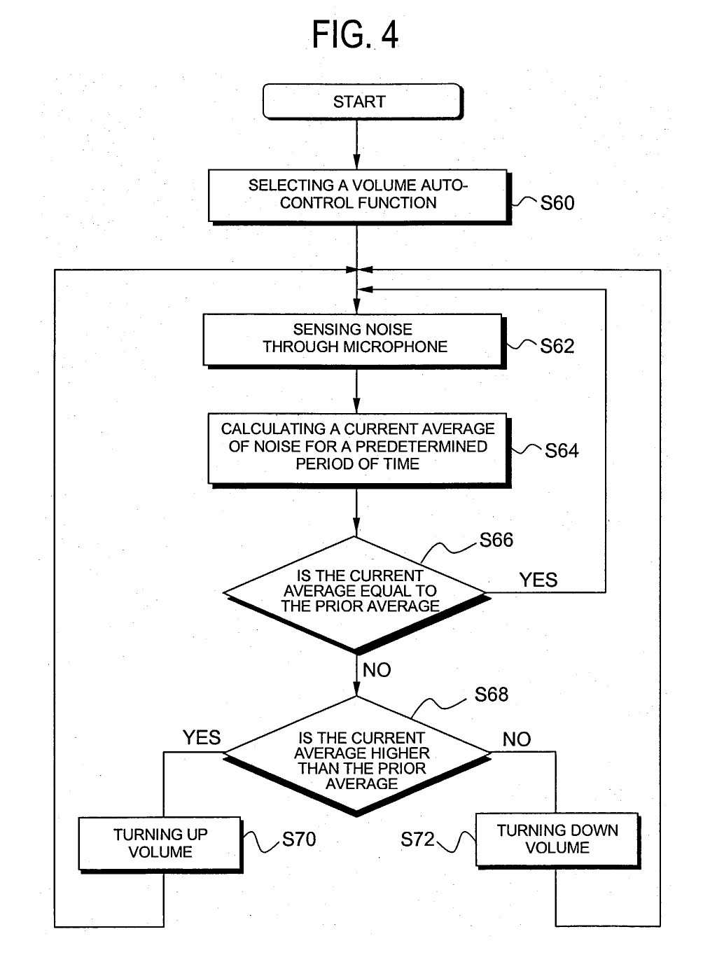

Another method of automatically controlling sound according to the present invention is illustrated in FIG. 4. In the method illustrated in FIG. 4, the user selects a volume auto-control function through the user selection part 20 at operation S60. The micro controller 12 receives the external noise through the microphone 9 at operation S62, and calculates an average of the input external noise for a predetermined period of time at operation S64. The micro controller 12 determines whether the calculated average of the input external noise (current average) is equal to a calculated average for a prior predetermined period of time (prior average) at operation S66. If the current average equals the prior average, the method returns to operation S62.

If the current average is not equal to the prior average, the micro controller 12 determines at operation S68 whether the current average is higher than the prior average. If the current average is higher than the prior average, the micro controller 12 instructs the volume controller 14 to turn up the volume at operation S70 and returns to operation S62. If the current average is not equal to or higher than the prior average, the micro controller 12 instructs the volume controller 14 to turn down the volume at operation S72 and returns to operation 62.

Since the micro controller 12 calculates the average of the external noise for the predetermined period of time and determines the noise level on the basis of the calculated average of the external noise, the volume level does not suddenly change even if the external noise suddenly changes.

Consequently, volume level is automatically controlled according to a change of an external noise without additional circuit elements.

As described above, the present invention provides a volume control system and a volume control method for a portable computer, in which circuit elements for volume auto-control function is decreased.

Although a few embodiments of the present invention have been shown and described, it would be appreciated by those skilled in the art that changes may be made in these embodiments without departing from the principles and spirit of the invention, the scope of which is defined in the claims and their equivalents.

What is claimed is:

1. A volume control system for a portable computer having a speaker, the volume control system comprising:
a volume controller which outputs a volume control signal:
an audio processing circuit which adjusts a volume of sound in response to the volume control signal and outputs a sound signal having an adjusted volume to the speaker;
a user selection part which selects a volume auto-control function;
a noise sensor which senses a noise external of the computer;
a volume set up table which lists volume levels corresponding to noise levels graded by loudness of the external noise; and
a micro controller which:
determines a noise level of the external noise based on the sensed external noise,
reads a volume level corresponding to the determined noise level from the volume set up table, and
controls the volume controller to adjust the volume where the volume auto-control function is selected.

2. The volume control system according to claim 1, wherein the noise sensor comprises a microphone.

3. The volume control system according to claim 1, wherein:
the noise sensor converts the external noise to an analog noise signal; and
the micro controller further comprises an A/D converter pin which converts the analog noise signal into a digital signal.

4. A method of controlling sound volume for a portable computer comprising:
storing a volume set up table in which volume levels corresponding to noise levels graded by the loudness of an external noise are previously listed;
sensing the external noise;
determining the noise level of the sensed noise; and
adjusting the volume of the sound according to the determined noise level based on the volume set up table.

5. The method of claim 4, wherein the sensing of the external noise comprises:
converting the external noise to an analog signal;
converting the analog signal to a digital signal;
calculating an average noise for a predetermined period of time; and
selecting a volume level from the set up table based on the calculated average noise.

6. A method of controlling sound volume for a portable computer comprising:
sensing noise external to the computer;
calculating a current average of the external noise for a predetermined period of time;
comparing the external noise with a predetermined value; and
increasing the sound volume where the current average of the external noise exceeds the predetermined value.

7. The method of claim 6, further comprising:
setting a prior calculated average of the external noise as the predetermined value.

8. A method of controlling sound volume for a portable computer comprising:
sensing noise external to the computer;
calculating a current average of the external noise for a predetermined period of time;
comparing the calculated predetermined average of the external noise external noise with a predetermined value; and
decreasing the sound volume where the external noise is less than the predetermined value.

9. The method of claim 8, further comprising:
setting a prior calculated average of the external noise as the predetermined value.

10. A portable computer comprising:
a speaker;
an audio processing circuit which adjusts an audio signal supplied to the speaker in response to a control signal;
a noise sensor which determines a noise level external to the computer;
a microcontroller which calculates an average of the noise level and outputs the control signal based on the calculated average.

11. The portable computer of claim 10, further comprising:
a volume set up table which lists volume levels corresponding to loudness of the external noise; and
wherein the micro controller determines the control signal based on determining a correspondence between the calculated average noise level and one of the listed volume levels.

12. The portable computer of claim 10, wherein:
the micro controller calculates the average of the noise level for first and second predetermined periods of time; and
determines the control signal based on comparing the calculated average for the second predetermined period of time with the calculated average for the first predetermined period of time.

13. The portable computer of claim 12, wherein:
the micro controller outputs the control signal to increase the audio signal where the calculated average for the second predetermined period of time is greater than the calculated average for the first predetermined period of time.

14. The portable computer of claim 12, wherein:
the micro controller outputs the control signal to decrease the audio signal where the calculated average for the second predetermined period of time is less than the calculated average for the first predetermined period of time.

15. The portable computer of claim 12, wherein the micro controller:
outputs the control signal to increase the audio signal where the calculated average for the second predetermined period of time is greater than the calculated average for the first predetermined period of time; and
outputs the control signal to decrease the audio signal where the calculated average for the second predetermined period of time is less than the calculated average for the first predetermined period of time.
